(19) United States
(12) Patent Application Publication
(10) Pub. No.: US 2003/0141103 A1
(43) Pub. Date: Jul. 31, 2003

(54) PCB solder pad geometry including patterns improving solder coverage

(76) Inventors: Wee Lee Ng, Richardson, TX (US); Buford H. Carter JR., Richardson, TX (US)

Correspondence Address: Mike Skrehot, Texas Instruments Incorporated, M/S 3999, P.O. Box 655474, Dallas, TX, 75265, US

(21) Appl. No.: 10/066,246

(22) Filed: Jan. 31, 2002

(51) Int. Cl. H05K 3/34

(52) U.S. Cl. 174/250; 361/777; 228/180.21

(57) ABSTRACT

An improved PCB bond pad (22, 40, 50, 60) having a dimensioned geometry that improves solder re-flow and facilitates outgassing of bubbles generated in solder during re-flow to reduce voiding. The improved PCB bond pad design is particularly useful to improve re-flow for RF devices that are sensitive to voiding in solder after re-flow and provides an excellent ground plane/heat sink connection. The present invention includes a printed circuit board (PCB) having a patterned bond pad defining solder channels (30, 42, 52, and 62). During re-flow, bubbles outgas through the channels from under a contact pad (34) of an overlying IC device thereby providing nearly 100 percent solder coverage at interface of device exposed pad and PCB bond pad.

### FIELD OF THE INVENTION

The present invention is generally related to printed circuit boards (PCBs), and more particularly to PCBs including large bond pads adapted to receive RF devices and route RF signals thereacross to a heat sink/ground plane.

### BACKGROUND OF THE INVENTION

Printed circuit boards (PCBs) typically comprise of a non-conductive layer of material having electrically conductive circuit traces extending thereacross, either as a single layer or multi-layer of traces. These traces are also patterned to define bond pads adapted to be soldered to electronic circuitry disposed thereupon and to efficiently route signals therebetween via the circuit traces. Preferably, these traces are formed using pattern (masking) and etching techniques well known in the industry. Typically, the circuit traces comprise of copper or other electrically conductive materials suited to provide low impedance signal paths between the associated electrical components.

Bond pads are typically defined in designated areas in the circuitry for receiving these electrical components. These bond pads are typically comprised of electrically conductive materials well adapted to receive the initial placement of the components thereon, and also facilitate adequate re-flow of the solder paste thereacross when the PCB is processed through a re-flow process. Copper is a preferable choice for bond pads, but is subject to oxidation. Accordingly, the bond pads may be coated with hot re-flowed solder or gold plating so as to provide both high electrical and thermal conductivity, are well suited for the re-flow process, and do not easily oxidize.

With respect to PCBs adapted to receive high power RF components, and route RF signals across the signal traces and large bond pads connected to an underlying heat sink/ground plane, there is a particular need that the solder coverage to the bond pad receiving the RF device after re-flow have substantially reduced voiding in the solder joint to allow effective communication of RF signals thereacross and sink heat. Currently, standard assembly processes may result in solder coverage with up to 50% voiding. A typical PCB 10 having a bond pad 12 adapted to solder to an exposed pad on the underside of an IC is shown in FIG. 1. This voiding is illustrated in FIG. 2, and is recognized as bubbling 14 which occurs within the solder 16 between the PCB bond pad 18 and an exposed solder pad on the underside of the IC during a re-flow process. While the conventional solder coverage including voiding may be adequate from a thermal conductivity stand point and provide good electrical connection for some devices, this voiding is a substantial problem particularly with respect to RF devices communicating RF signals to a ground plane as they react unpredictably to these voiding situations.

There is desired an improved PCB bond pad design which is well adapted to receive RF devices and route RF signals thereacross to a heat sink/ground plane, and which reduces the voiding problems inherent in conventional bond pad designs and re-flow procedure.

### SUMMARY OF THE INVENTION

The present invention achieves technical advantages as an improved printed circuit board and bond pad design whereby the bond pad is geometrically patterned to define channels therethrough, allowing the solder to outgas bubbles generated during a re-flow process from under the device being soldered. Preferably, the bond pad is patterned, such as to define channels, grooves, parallel lines, and/or radial lines, all which provide a path allowing a solder paste to re-flow and outgas from beneath the device being soldered to substantially reduce voiding to less than 10%. Particularly with RF devices needing an excellent connection to a ground plane/heat sink, this is a significant improvement over conventional printed circuit board and bond pad designs which are prone to produce unacceptable voiding.

The present invention requires only a simple modification to conventional printed circuit board fabrication techniques, providing that the bond pads have patterns defining channels not conductive to solder during re-flow to allow outgassing. This design realizes a bond pad having between about 70 and 90% surface area coverage with the exposed pad of the overlying device mounted thereon, which achieves the technical advantages of improving solder re-flow behind the exposed pad into these recesses to facilitate outgassing of bubbles generated during re-flow to reduce voiding. With regards to RF devices, this is a significant improvement.

### BRIEF DESCRIPTION OF THE DRAWINGS

FIG. 1 is a prior art PCB design with a large bond pad adapted to solder to an exposed pad of an overlying IC;

FIG. 2 is an illustration of a prior art bond pad design soldered to an exposed pad of an overlying IC with voiding existing in the solder after a re-flow process;

FIG. 3 illustrates a PCB according to the present invention with an improved channeled bond pad facilitating outgassing during re-flow;

FIG. 4 depicts an enlarged view of the bond pad embodiment of FIG. 3 whereby the recesses are defined in a radial pattern;

FIG. 5 is a top view of a solder pad/bond pad combination according to the present invention providing recesses/channels between portions of the bond pad to improve solder re-flow and outgassing during re-flow, whereby this design is embodied as a series of grooves defined in a lattice arrangement;

FIG. 6 depicts another embodiment including radial lines terminating at alternative distances from a focal point and with an increased number of radial lines as compared to the embodiment of FIG. 4;

FIG. 7 is an embodiment depicting a series of parallel grooves defined through the bond pad;

FIG. 8 depicts the embodiment of FIG. 4 after a re-flow processes, depicting the uniform solder coverage on the bond pad with minimal voiding as represented by the bubbles;

FIG. 9 depicts the embodiment of FIG. 5 after a re-flow process also depicting uniform solder coverage on the bond pad with minimal voiding after re-flow;

FIG. 10 depicts the bond pad embodiment corresponding to FIG. 6 after a re-flow process;

FIG. 11 depicts the bond pad embodiment of FIG. 7 after a re-flow process;

FIGS. 12 and 13 depict diagrams of thermal efficiency for the various designs for solder and palladium plated devices, respectively; and

FIG. 14 depicts the methodology for fabricating the PCB with the improved bond pad design minimizing voiding.

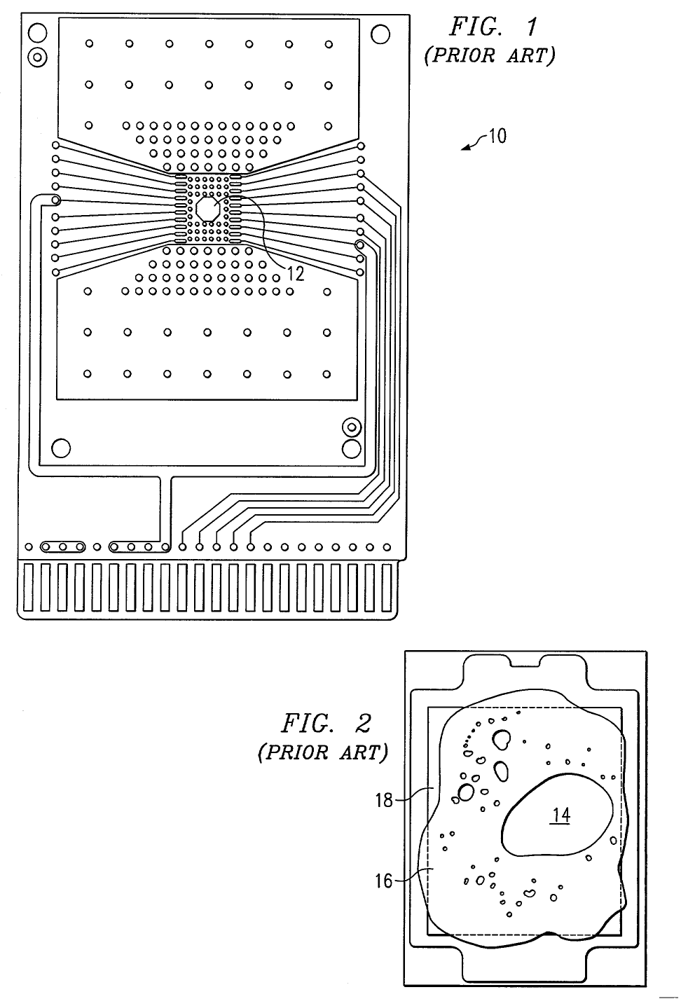

### DETAILED DESCRIPTION OF THE PREFERRED EMBODIMENT

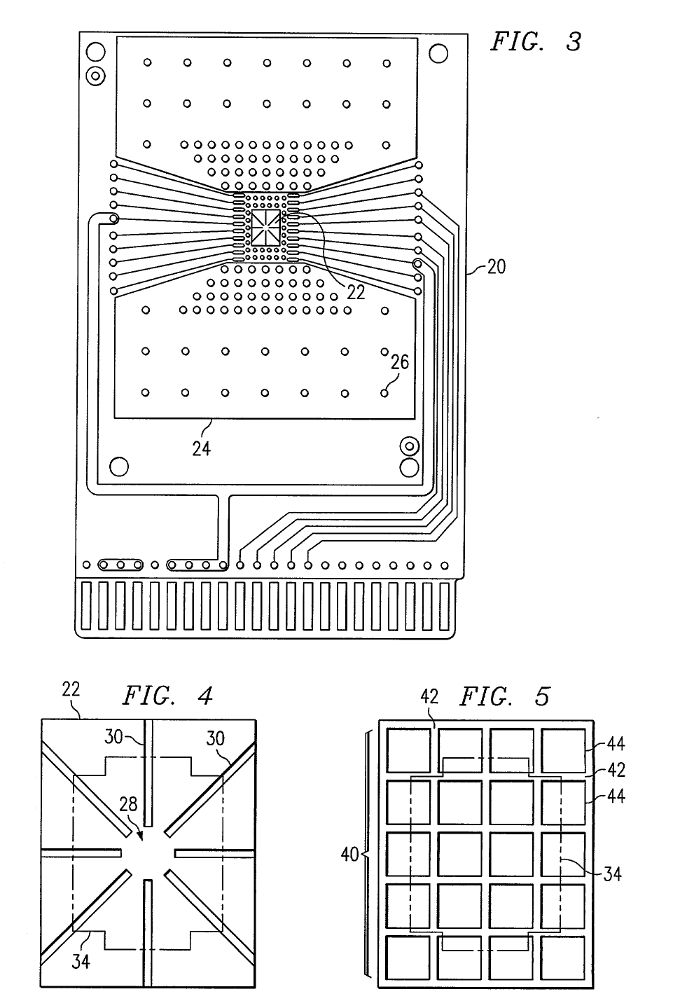

Referring now to FIG. 3, there is depicted an improved PCB 20 with an improved bond pad arrangement designed generally at 22. Bond pad 22 is seen to form a portion of the printed circuit board which is in electrical and thermal contact with the larger heat sink/ground plane 24, which may include vias/feed-throughs 26 extending to another layer forming a heat sink and ground plane. Advantageously, as shown in FIG. 4, the PCB bond pad 22 is patterned and/or partitioned by channels 30 to facilitate the re-flow of solder paste during a re-flow process and facilitate outgassing of bubbles generated in the solder during re-flow to substantially reduce voiding therein. The channels 30 defined in the bond pad 22 render the bond pad 22 non-planar. The outline of an overlying exposed solder pad 34 of an overlying IC illustrates the orientation of the solder pad 34 over the significantly larger bond pad 22. Advantageously, rather than conventionally having one large continuous planar bond pad, solder paste flow channels 30 are defined which permit the solder paste to flow across the bond pad, inducing outgassing of bubbles in the channels, and achieving a good electrical and thermal interface.

The grooves 30 terminate at, but are spaced slightly from, a focal point 28 defined generally beneath the center of the overlying solder pad 34. This bond pad design 22 also facilitates the solder paste to flow through the corresponding grooves 30 during a re-flow process, facilitating outgassing of bubbles generated in the solder during re-flow to minimize voiding in the solder as previously described. In the embodiment shown in FIG. 4, the portion of the underlying bond pad 22 that is directly below the overlaying solder pad 34 may have a surface area of 75%. These solder pad flow channels, embodied here as radial channels 30, radially direct any bubbles outwards from beneath the center of the overlying solder pad 34.

With regards to the embodiment of FIG. 5, another embodiment of a bond pad is shown as bond pad 40 seen to be partitioned by a plurality of horizontally and vertically extending channels 42 forming a lattice configuration. These channels define a plurality of rectangular bond pad portions 44 which collectively comprise the bond pad 40.

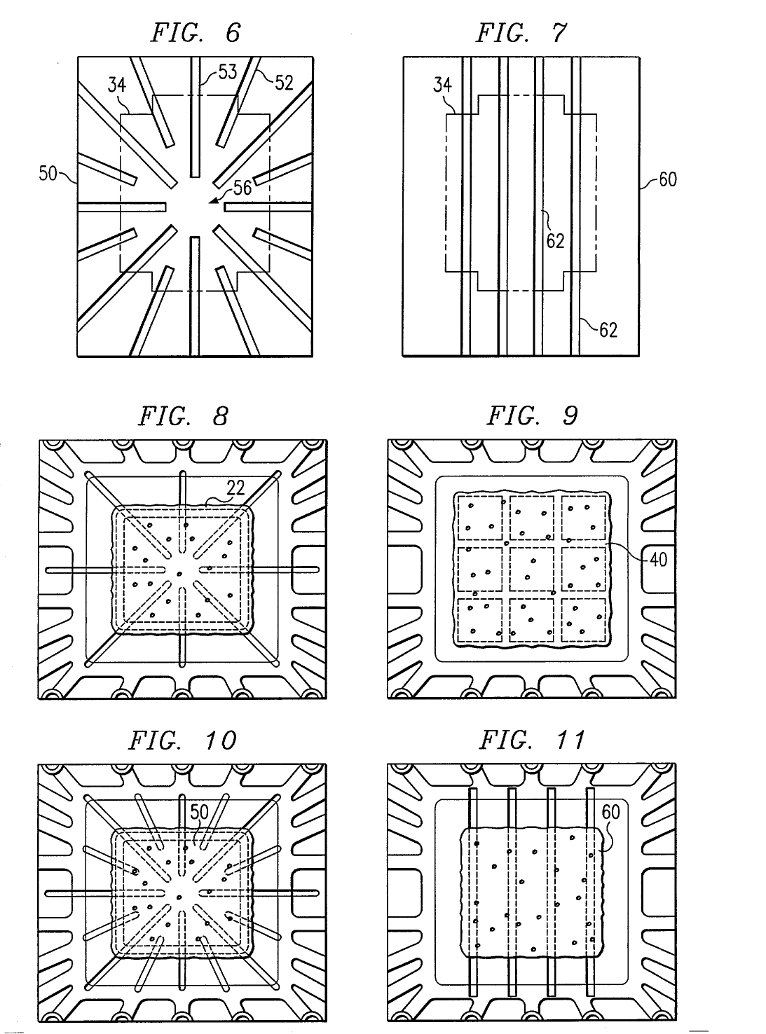

As appreciated in FIG. 5, the bond pad 40 area is significantly larger than the overlying corresponding solder pad 34, and may comprise an area 2× that of the corresponding solder pad 34. This large bond pad allows an adequate portion of solder paste to be applied prior to re-flow and accounts for shrinkage of solder paste during re-flow. As depicted in FIG. 5, the underlying bond pad portions 40 may have a contact area of approximately 69% of the corresponding overlying solder pad 34. However, for RF circuits components, a continuous solder connection is achieved with minimal voiding to achieve maximum RF operating characteristics, as is shown in FIG. 9 to be discussed shortly.

Referring now to FIG. 6, there is shown at 50 yet another embodiment similar to the bond pad arrangement 22 of FIG. 4, but including shorter radial channels 52 alternatingly disposed between the longer radial channels 53 as shown. These radial channels 52 provide additional solder re-flow channels beneath the corresponding solder pad 34 to facilitate the outgassing of bubbles from thereunder. These alternately disposed radial channels 52 extend towards the focal point 56, but terminate at a point more distant from focal point 56 than the distal ends of the longer channels 53, as shown. Each of these flow channels 52 & 53 are separated from one another by portions of the bond pad 50 exposing the PCB board to facilitate the outgassing of bubbles from beneath the solder pad 34.

Referring now to FIG. 7, there is depicted at 60 yet another embodiment of a bond pad with these solder flow channels depicted as a plurality of parallel channels 62 extending through the corresponding bond pad 60. In this embodiment, roughly 77% of the solder pad 34 overlies a corresponding portion of the bond pad 60, yet an excellent thermal and RF solder contact is achieved.

As previously described, the channels extending through the corresponding bond pad are defined during the mask and etching process which defines the electrical circuit traces on the printed circuit board as well as the corresponding bond pads. Thus, the conductive patterned portions of the bond pad are disposed above the printed circuit board base material, including those PCB portions defining channels between corresponding portions of the bond pads. A solder mask is applied to the bond pads after this mask and etching process. A solderable protective coating such as hot re-flowed solder or gold plating is applied and thus is non-planar due to the underlying non-planar bond pad structure.

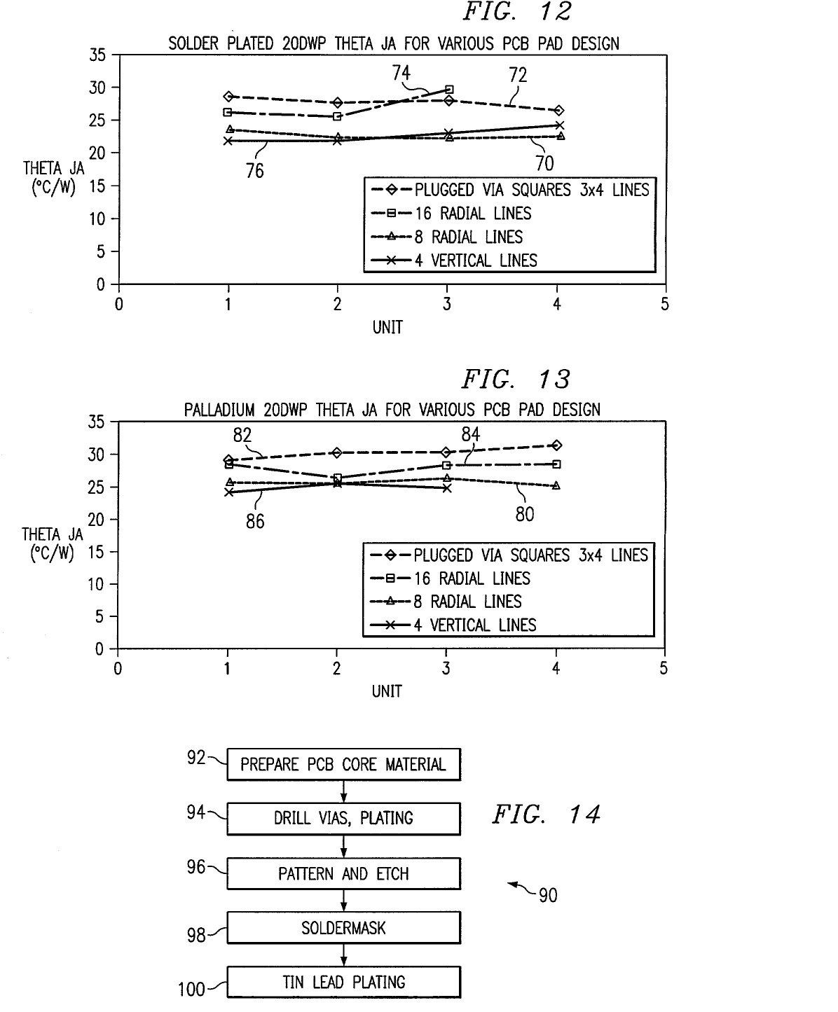

Turning now to FIGS. 8-11, there is depicted the bond pad structures corresponding to the embodiments of FIGS. 4-7, depicting solder uniformly flowed across the upper surface of the bond pad, and also fills the corresponding channels. Importantly, there is depicted the substantial reduction of voiding in the solder after re-flow due to the induced and permitted outgassing of bubbles generated in the solder during re-flow. Test results have achieved voiding in the range of no greater than 10%, which is a significant improvement over the nearly 50% voiding which may occur in some conventional designs. Additional solder paste is provided as compared to conventional designs, which has nominal cost and process concerns, and which ultimately flows under the corresponding solder pad 34 into the corresponding solder flow channels, as depicted by the shading.

Referring now to FIG. 12 there is depicted a graph of the thermal performance of the various designs using solder plated devices. Line 70 illustrates the thermal performance of the arrangement 22 depicted in FIG. 4, line 72 depicts the performance of the arrangement 40 shown in FIG. 5, line 74 depicts the thermal performance of the arrangement 50 shown in FIG. 6, and line 76 depicts the thermal performance of the design 60 shown in FIG. 7. All four designs are seen to have excellent thermal performance. As a reference, devices were assembled on to PCB's using Alpha 606 solder paste; a 0.006 inch thick metal stencil with an aperture equal to the exposed pad on the bottom of the device and processed though a Heller 1500 infrared solder re-flow oven operating at a belt speed of 50 centimeters per minutes. The thermal impedance measurement was performed at 2 watts.

Referring now to FIG. 13, there is depicted the same thermal performance information whereby the device leads and exposed pad had a palladium finish instead of solder plate. The lines 80, 82, 84 and 86 all correspond to the designs 22, 40, 50 and 60 depicted in FIGS. 4-7, respectively.

Referring now to FIG. 14, there is shown a flow diagram of a printed circuit board fabrication methodology 90 which may be used to fabricate the bond pad arrangements previously discussed. At step 92, the printed circuit board core material is prepared and shaped according to the particular design desired.

At step 94, vias are drilled through the PCB core material at locations according to the PCB design, and these vias are plated as is conventional in the art.

At step 96, both the electrical circuit traces and the bond pads are defined using a conventional pattern and etching process. Importantly, it is during this step 96 that this process is modified from conventional approaches, whereby the bond pads are patterned to define solder flow channels therethrough as previously described. This pattern and etching is well known in the industry, however, the partitioning and shaping of the bond pad is unique.

At step 98, the solder mask is applied to define and expose the bond pads.

Finally, at step 100, hot re-flow solder may be applied to coat the exposed copper pads and vias.

Though the invention has been described with respect to a specific preferred embodiment, many variations and modifications will become apparent to those skilled in the art upon reading the present application. It is therefore the intention that the appended claims be interpreted as broadly as possible in view of the prior art to include all such variations and modifications.

We claim:

1. A printed circuit board (PCB) comprising:
a first layer of non-conductive material; and
a bond pad comprising a patterned conductive second material disposed upon said first layer said patterned bond pad defining a channel therein facilitating outgassing of bubbles via the channel.

2. The PCB as specified in claim 1 wherein said bond pad is dimensioned to render said pad non-planar.

3. The PCB as specified in claim 1 wherein said bond pad is dimensioned to define a plurality of said channels extending laterally through said bond pad.

4. The PCB as specified in claim 1 further comprising a plurality of pads disposed about said bond pad and being adapted to receive a multi-pin integrated circuit being centered over the bond pad.

5. The PCB as specified in claim 3 wherein said channels are defined in a radial pattern.

6. The PCB as specified in claim 5 wherein said radial lines terminate at a point distant from a focal point.

7. The PCB as specified in claim 6 wherein said radial lines have different lengths.

8. The PCB as specified in claim 6 wherein some of the radial lines terminate different distances from the focal point.

9. The PCB as specified in claim 4 wherein said channels are defined as multiple lines.

10. The PCB as specified in claim 9 wherein said channels are defined as parallel said lines.

11. The PCB as specified in claim 9 wherein said multiple lines intersect.

12. In combination;
an integrated circuit having a lower surface including an exposed solder pad;
a first layer of non-conductive material; and
a bond pad opposed said contact pad and comprising a patterned conductive second material disposed upon said first layer said patterned bond pad defining a channel therein facilitating outgassing of bubbles via the channel.

13. The PCB as specified in claim 12 wherein said bond pad is dimensioned to render said pad non-planar.

14. The PCB as specified in claim 12 wherein said bond pad is dimensioned to define a plurality of said channels extending laterally through said bond pad.

15. The PCB as specified in claim 12 wherein said channels are defined in a radial pattern.

16. The PCB as specified in claim 12 wherein said channels are defined as multiple lines.

17. A method of fabricating a printed circuit board (PCB) having electrically conductive signal traces thereon, comprising the steps of:
defining and patterning a bond pad to define a channel laterally through the bond pad adapted to facilitate outgassing of bubbles generated in solder during re-flow of solder upon the bond pad.

18. The method of fabricating as specified in claim 17 wherein the bond pad is dimensioned to render the bond pad non-planar.
